(19) United States
(12) Patent Application Publication
(10) Pub. No.: US 2025/0275121 A1
(43) Pub. Date: Aug. 28, 2025

(54) SEMICONDUCTOR MEMORY DEVICE AND MANUFACTURING METHOD THEREOF

(71) Applicant: NANYA TECHNOLOGY CORPORATION, New Taipei city (TW)

(72) Inventors: Chen-Hao LIEN, New Taipei City (TW); Jin-Sheng LIOU, New Taipei City (TW)

(21) Appl. No.: 18/584,075

(22) Filed: Feb. 22, 2024

(51) Int. Cl. H10B 12/00

(52) U.S. Cl. CPC H10B 12/482; H10B 12/02

(57) ABSTRACT

A semiconductor memory device manufacturing method includes the following steps. A bit line structure is formed on a substrate, wherein the bit line structure includes a bit line conductive portion and a bit line dielectric portion. A silicon carbon oxide (SiCO) layer is formed over the bit line structure. A hydrogen plasma process is performed to the SiCO layer. A hydrofluoric acid etching process is performed to the SiCO layer; and a silicon nitride layer is formed over the bit line structure and the remaining SiCO layer that is not etched by the hydrofluoric acid etching process.

### BACKGROUND

### Field of Disclosure

The present disclosure relates to a semiconductor memory device and manufacturing method thereof.

### Description of Related Art

An integrated circuit (IC) device (also referred to as a semiconductor chip) can contain millions of transistors and other circuit elements that are fabricated on a single silicon crystal substrate (wafer). In a semiconductor memory device, a bit line is a crucial component responsible for carrying data during read and write operations. It connects to memory cells within the array and allows the transfer of binary information During a read operation, the bit line senses the state of the memory cell, while during a write operation, it facilitates the updating of data within the cell. The bit line structure typically involves metal lines, transistors, and other elements, ensuring efficient data transfer and storage in the memory device.

### SUMMARY

The present disclosure provides semiconductor memory devices and manufacturing methods thereof to deal with the needs of the prior art problems.

In one or more embodiments, a semiconductor memory device manufacturing method including: forming a bit line structure on a substrate, wherein the bit line structure comprises a bit line conductive portion and a bit line dielectric portion; forming a silicon carbon oxide (SiCO) layer over the bit line structure; performing a hydrogen plasma process to the SiCO layer; performing a hydrofluoric acid etching process to the SiCO layer; and forming a silicon nitride layer over the bit line structure and the remaining SiCO layer that is not etched by the hydrofluoric acid etching process.

In one or more embodiments, the method further includes: performing a nitride etching process to the silicon nitride layer until the bit line dielectric portion is exposed.

In one or more embodiments, the hydrogen plasma process is performed by applying a bias voltage ranging from 100V to 400V.

In one or more embodiments, the SiCO layer consists of 37% silicon, 48% oxygen and 15% carbon.

In one or more embodiments, the bit line dielectric portion is on a top of the bit line conductive portion.

In one or more embodiments, the bit line conductive portion comprises a tungsten portion, a polysilicon portion, and a diffusion barrier layer between the tungsten portion and the polysilicon portion.

In one or more embodiments, a top end of the remaining SiCO layer is fully enclosed by the bit line dielectric portion and the remaining silicon nitride layer that is not etched by the nitride etching process.

In one or more embodiments, a semiconductor memory device manufacturing method including: forming a bit line structure on a substrate, wherein the bit line structure comprises a bit line conductive portion and a bit line dielectric portion; forming a silicon carbon oxide (SiCO) layer over the bit line structure; performing a hydrogen plasma process to oxidize portions of the SiCO layer; performing a hydrofluoric acid etching process to remove the oxidized portions of the SiCO layer; and forming a silicon nitride layer over the bit line structure and the remaining SiCO layer that is not etched by the hydrofluoric acid etching process.

In one or more embodiments, the SiCO layer consists of 37% silicon, 48% oxygen and 15% carbon.

In one or more embodiments, the oxidized portions of the SiCO layer consist of 60% oxygen and 40% silicon.

In one or more embodiments, the hydrogen plasma process is performed by applying a bias voltage ranging from 100V to 400V.

In one or more embodiments, the method further includes: performing a nitride etching process to the silicon nitride layer until the bit line dielectric portion is exposed.

In one or more embodiments, a top end of the remaining SiCO layer is fully enclosed by the bit line dielectric portion and the remaining silicon nitride layer that is not etched by the nitride etching process.

In one or more embodiments, the bit line dielectric portion is on a top of the bit line conductive portion.

In one or more embodiments, the bit line conductive portion comprises a tungsten portion, a polysilicon portion, and a diffusion barrier layer between the tungsten portion and the polysilicon portion.

In one or more embodiments, a semiconductor memory device includes a bit line structure on a substrate, wherein the bit line structure comprises a bit line conductive portion and a bit line dielectric portion; a silicon carbon oxide (SiCO) layer on a sidewall of the bit line structure; and a silicon nitride layer on the sidewall of the bit line structure, wherein a top end of the SiCO layer is fully enclosed by the bit line dielectric portion and the silicon nitride layer.

In one or more embodiments, a top portion of the bit line dielectric portion is not covered by the SiCO layer.

In one or more embodiments, the SiCO layer consists of 37% silicon, 48% oxygen and 15% carbon.

In one or more embodiments, the bit line dielectric portion is on a top of the bit line conductive portion.

In one or more embodiments, the bit line conductive portion comprises a tungsten portion, a polysilicon portion, and a diffusion barrier layer between the tungsten portion and the polysilicon portion.

In sum, the semiconductor memory device manufacturing method disclosed herein utilizes hydrogen plasma process to oxidize the unwanted portions of the SiCO layer and performing a hydrofluoric acid etching process to remove the oxidized portions of the SiCO layer. Therefore, the remaining SiCO layer is fully covered by the silicon nitride layer and no damage path for the remaining SiCO layer exists.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1-5 illustrate cross-sectional views of several steps of a semiconductor memory manufacturing process according to some embodiments of the present disclosure; and

FIG. 6 illustrates a flowchart of several steps of a semiconductor memory manufacturing process according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

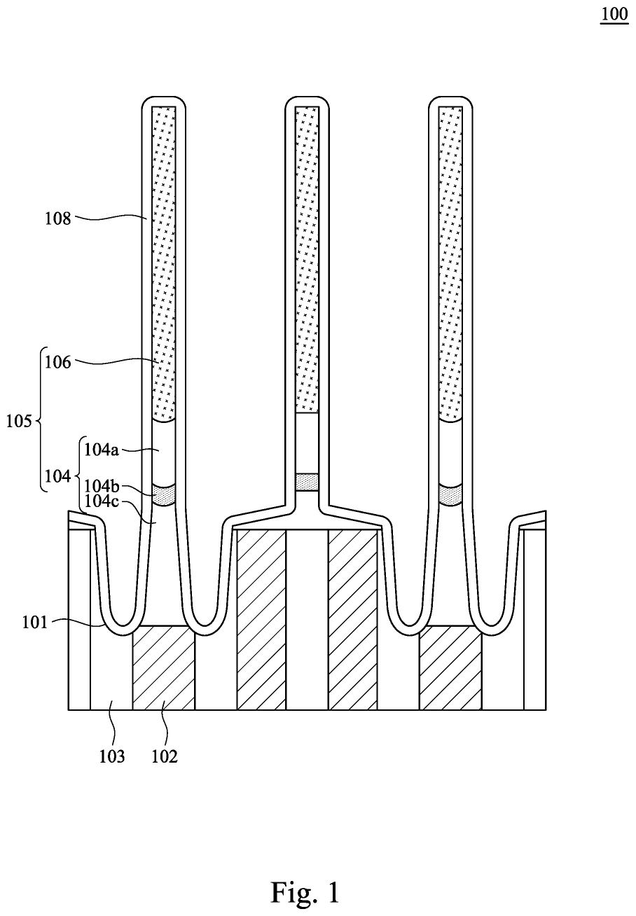

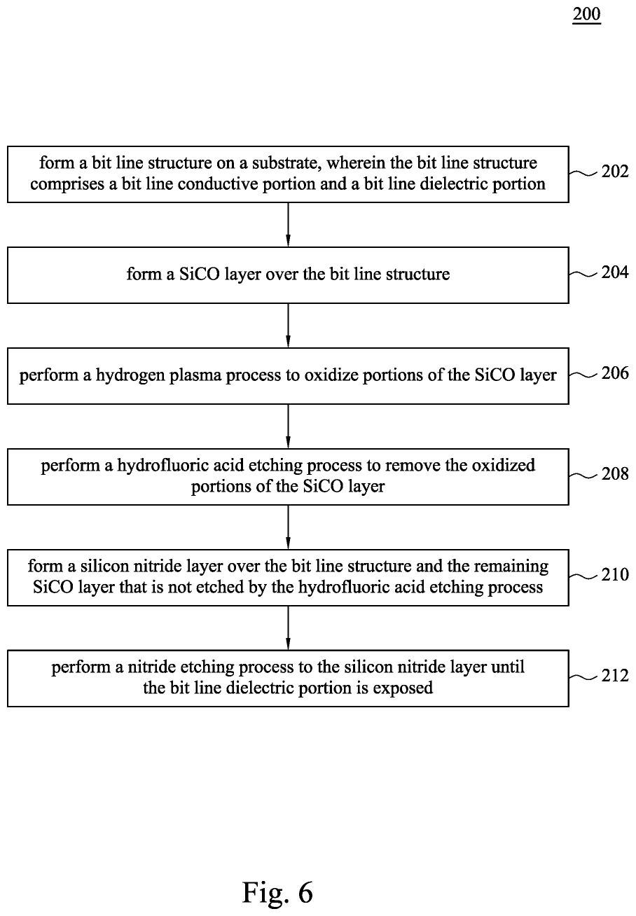

Reference is made to FIGS. 1-6, FIGS. 1-5 illustrate cross-sectional views of several steps of a semiconductor memory manufacturing process according to some embodiments of the present disclosure, and FIG. 6 illustrates a flowchart of several steps of a semiconductor memory manufacturing process 200 according to some embodiments of the present disclosure. The cross-sectional view illustrates a portion of a memory device 100 including bit line structures 105. A semiconductor substrate is processed to form active areas. Several steps are typically involved in semiconductor processing. A suitable semiconductor substrate, such as silicon (Si), is chosen based on the desired device specifications and requirements. A thin layer of silicon dioxide (SiO₂) may be on the surface of the substrate. This can be achieved through thermal oxidation, where the substrate is exposed to an oxygen-rich environment at high temperatures, or by using deposition techniques such as chemical vapor deposition (CVD) or plasma-enhanced chemical vapor deposition (PECVD). A layer of photosensitive material, known as photoresist, is coated onto the oxide layer. Then, expose the photoresist to ultraviolet (UV) light through a photomask containing the desired pattern. This step transfers the pattern onto the photoresist. The exposed photoresist is developed using a suitable developer solution. This selectively removes either the exposed (positive photoresist) or unexposed (negative photoresist) regions of the photoresist, leaving behind the desired pattern. An etching process, such as plasma etching or wet etching, is used to selectively remove the exposed oxide layer where the active area will be formed. The patterned photoresist acts as a mask, protecting the regions where the oxide is desired. Ion implantation is performed to introduce p-type or n-type dopant atoms into the exposed semiconductor substrate regions where the active devices will be formed. The dopants modify the electrical properties of the substrate, creating regions with desired conductivity characteristics. The implanted dopants are activated and crystal lattice damage caused by the implantation process is repaired through an annealing process. This step typically involves subjecting the substrate to high temperatures for a specific duration.

In step 202 of the process 200, a bit line structure 105 is formed in a bit line trench 101 of a substrate including silicon 102 and silicon oxide 103. The bit line structure 105 includes a bit line conductive portion 104 and a bit line dielectric portion 106. The bit line dielectric portion 106 is above and in contact with a top of the bit line conductive portion 104. The bit line conductive portion 104 includes a tungsten portion 104a, a polysilicon portion 104c, and a diffusion barrier layer 104b between the tungsten portion 104a and the polysilicon portion 104c. To form a bit line structure 105 in a bit line trench 101 of a substrate may include a multi-step process as followed. The bit line trench 101 can be formed in the substrate using lithography and etching techniques. The polysilicon portion 104c can be formed as a conductive material in semiconductor processes. A diffusion barrier layer 104b can be deposited within the trench 101 to prevent intermixing of materials between the tungsten portion 104a and the polysilicon portion 104c of the bit line structure 105. The tungsten portion 104a can be deposited on the diffusion barrier layer 104b. The bit line dielectric portion 106 can be formed by depositing a dielectric material above the bit line conductive portion 104. A planarization technique, such as chemical mechanical polishing (CMP), can be performed to remove excess dielectric material and create a smooth, flat surface.

In step 204 of the process 200 (referring to FIG. 1), a silicon carbon oxide (SiCO) layer 108 can be formed over the bit line structure 105 as a low-k dielectric layer. Forming the SiCO layer 108 may involve various methods, and the choice depends on the specific manufacturing process and equipment available.

In one or more embodiments, the SiCO layer 108 can be formed by a chemical vapor deposition (CVD). For example, the substrate can be loaded into a CVD chamber, precursor gases containing silicon, carbon, and oxygen can be introduced into the CVD chamber, and deposition parameters like temperature, pressure, and flow rates can be controlled to achieve desired thickness and dielectric constant for the SiCO layer 108.

In one or more embodiments, the SiCO layer 108 can be formed by a spin-on deposition. For example, a liquid precursor solution containing silicon, carbon, and oxygen can be applied on the substrate, the substrate can be spun to achieve a uniform layer, the spin-on material can be cured to remove solvents and create the SiCO layer.

In one or more embodiments, the SiCO layer 108 can be formed by an atomic layer deposition (ALD). For example, the substrate can be alternately exposed to precursor gases for silicon, carbon, and oxygen in a cyclic fashion, each exposure resulting in a monolayer deposition, and the cycles are repeated until the desired SiCO thickness is achieved.

In one or more embodiments, the SiCO layer 108 can be formed by a plasma-enhanced chemical vapor deposition (PECVD). For example, the substrate can be loaded into a PECVD chamber, a combination of silicon, carbon, and oxygen precursors can be applied, and a plasma can be introduced to enhance the chemical reactions and promote film deposition.

In one or more embodiments, the SiCO layer 108 can be formed by a physical vapor deposition (PVD). For example, the substrate can be loaded into a PVD chamber, silicon, carbon, and oxygen-containing targets can be evaporated or sputtered, and the vaporized materials are condensed onto the substrate to form the SiCO layer.

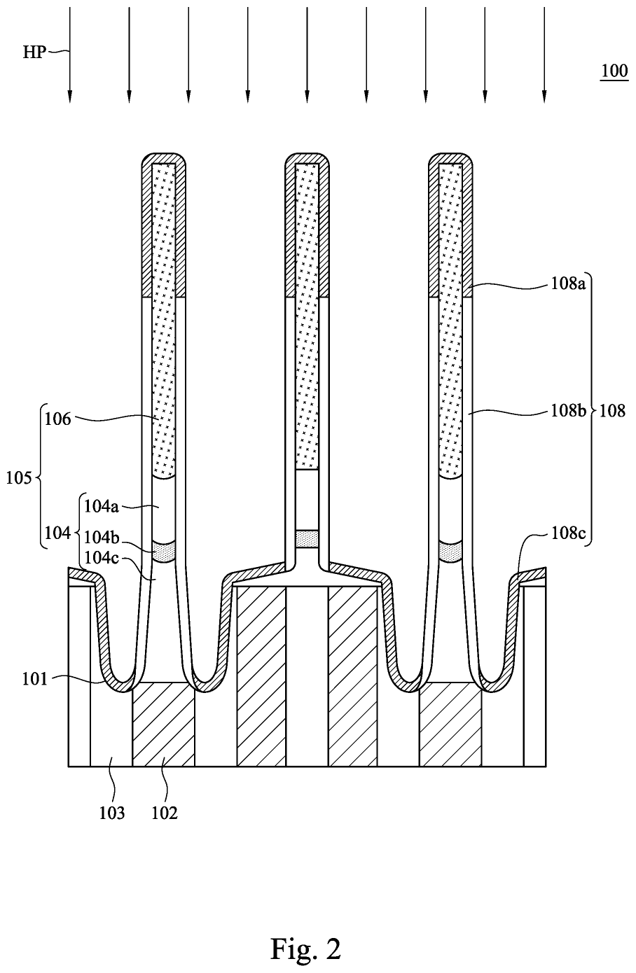

In step 206 of the process 200 (referring to FIG. 2), a hydrogen (H2) plasma process HP can be performed to oxidize portions of the SiCO layer 108. For example, introduce hydrogen (H₂) gas can be introduced into a chamber of a plasma system, creating a low-pressure environment. First, a RF (radio frequency) or microwave power is applied to generate a plasma. This energized state will facilitate chemical reactions with the SiCO layer, causing oxidation. Process parameters such as gas flow rate, pressure, and power can be controlled to achieve the desired oxidation level.

In one or more embodiments, portions (108a, 108c) are oxidized by the hydrogen plasma process HP. In one or more embodiments, the hydrogen plasma process HP is performed by applying a bias voltage ranging from 100V to 400V. For example, the impact of the ion energy on the oxidized portions of the SiCO layer 108 has been investigated by applying a bias voltage between 100V and 400V. In one or more embodiments, the SiCO layer consists of 37% silicon, 48% oxygen and 15% carbon. In one or more embodiments, the oxidized portions of the SiCO layer consist of 60% oxygen and 40% silicon.

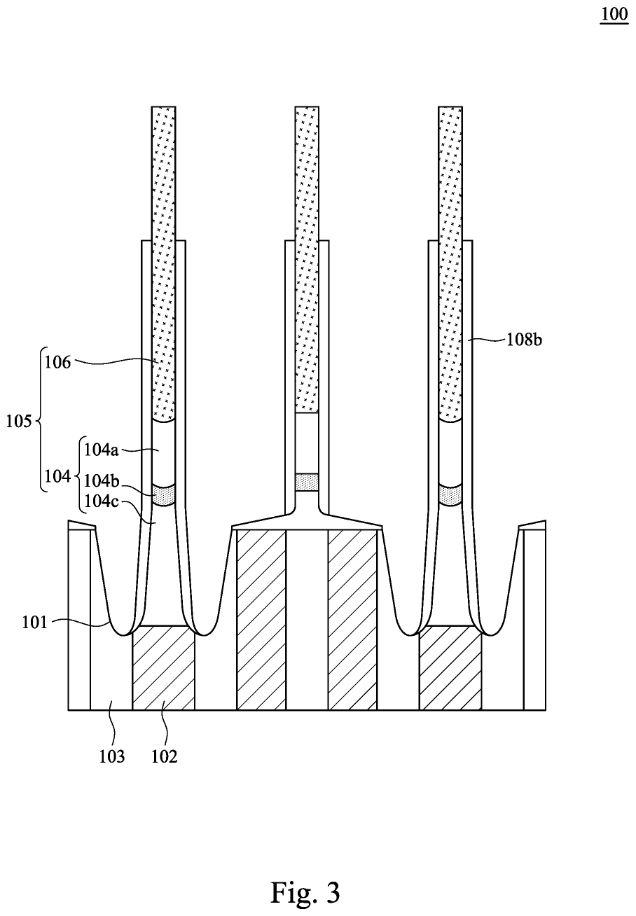

In step 208 of the process 200 (referring to FIG. 3), a hydrofluoric acid (HF) etching process is performed to remove the oxidized portions (108a, 108c) of the SiCO layer. In one or more embodiments, the HF etching process can be a deionized water diluted HF etching, e.g., HF 1% acid solution. In one or more embodiments, the SiCO layer 108 damage consumption has been measured as a function of HF 1% dip time. For a 100V bias voltage applied during the H₂ plasma, the oxidized portions of the SiCO layer has a thickness of about 6 nanometers. For a 250V bias voltage applied during the H₂ plasma, the oxidized portions of the SiCO layer has a thickness of about 10 nanometers. For a 400V bias voltage applied during the H₂ plasma, the oxidized portions of the SiCO layer has a thickness of about 16 nanometers.

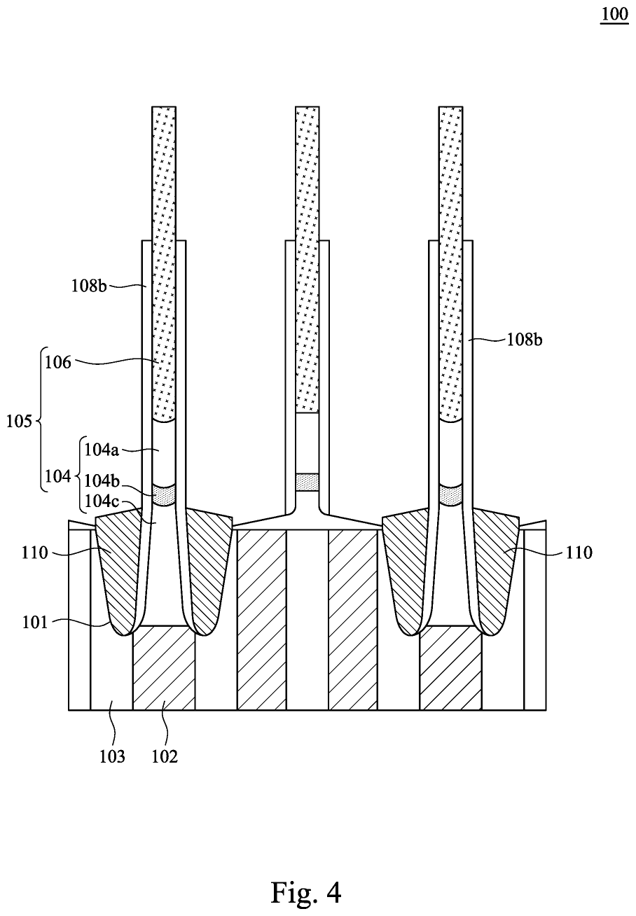

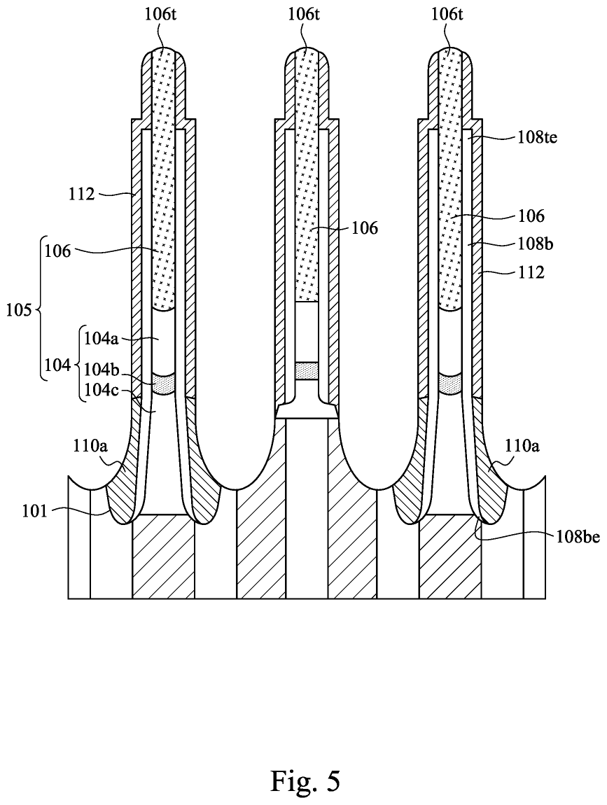

In step 210 of the process 200 (referring to FIGS. 4 and 5), a silicon nitride layer can be formed over the bit line structure 105 and the remaining SiCO layer 108b that is not etched by the hydrofluoric acid etching process. For example, a first silicon nitride layer 110 can be deposited to refill the bit line trench 101 of a substrate and a second silicon nitride layer 112 can be deposited over the bit line structure 105 and the remaining SiCO layer 108b that is not etched by the hydrofluoric acid etching process. In one or more embodiments, the second silicon nitride layer 112 can be deposited using an atomic layer deposition (ALD) to be a conformal layer over the bit line structure 105 and the remaining SiCO layer 108b and connected to the first silicon nitride layer 110.

In step 212 of the process 200 (referring to FIG. 5), a nitride etching process can be performed to the first and second silicon nitride layers (110, 112) until a top portion 106t of the bit line dielectric portion 106 is exposed. In one or more embodiments, a top end 108te of the remaining SiCO layer 108b is fully enclosed by the bit line dielectric portion 106 and the remaining second silicon nitride layer 112 that is not etched by the nitride etching process. In one or more embodiments, a bottom end 108be of the remaining SiCO layer is fully covered by the first nitride layer 110a that is not etched by the nitride etching process. Therefore, there is no damage path for the remaining SiCO layer 108b.

In sum, the semiconductor memory device manufacturing method disclosed herein utilizes hydrogen plasma process to oxidize the unwanted portions of the SiCO layer and performing a hydrofluoric acid etching process to remove the oxidized portions of the SiCO layer. Therefore, the remaining SiCO layer is fully covered by the silicon nitride layer and no damage path for the remaining SiCO layer exists.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor memory device manufacturing method comprising:
forming a bit line structure on a substrate, wherein the bit line structure comprises a bit line conductive portion and a bit line dielectric portion;
forming a silicon carbon oxide (SiCO) layer over the bit line structure;
performing a hydrogen plasma process to the SiCO layer;
performing a hydrofluoric acid etching process to the SiCO layer; and
forming a silicon nitride layer over the bit line structure and the remaining SiCO layer that is not etched by the hydrofluoric acid etching process.

2. The method of claim 1 further comprising: performing a nitride etching process to the silicon nitride layer until the bit line dielectric portion is exposed.

3. The method of claim 1, wherein the hydrogen plasma process is performed by applying a bias voltage ranging from 100V to 400V.

4. The method of claim 1, wherein the SiCO layer consists of 37% silicon, 48% oxygen and 15% carbon.

5. The method of claim 1, wherein the bit line dielectric portion is on a top of the bit line conductive portion.

6. The method of claim 1, wherein the bit line conductive portion comprises a tungsten portion, a polysilicon portion, and a diffusion barrier layer between the tungsten portion and the polysilicon portion.

7. The method of claim 2, wherein a top end of the remaining SiCO layer is fully enclosed by the bit line dielectric portion and the remaining silicon nitride layer that is not etched by the nitride etching process.

8. A semiconductor memory device manufacturing method comprising:
forming a bit line structure on a substrate, wherein the bit line structure comprises a bit line conductive portion and a bit line dielectric portion;
forming a silicon carbon oxide (SiCO) layer over the bit line structure;
performing a hydrogen plasma process to oxidize portions of the SiCO layer;
performing a hydrofluoric acid etching process to remove the oxidized portions of the SiCO layer; and
forming a silicon nitride layer over the bit line structure and the remaining SiCO layer that is not etched by the hydrofluoric acid etching process.

9. The method of claim 8, wherein the SiCO layer consists of 37% silicon, 48% oxygen and 15% carbon.

10. The method of claim 8, wherein the oxidized portions of the SiCO layer consist of 60% oxygen and 40% silicon.

11. The method of claim 8, wherein the hydrogen plasma process is performed by applying a bias voltage ranging from 100V to 400V.

12. The method of claim 8 further comprising: performing a nitride etching process to the silicon nitride layer until the bit line dielectric portion is exposed.

13. The method of claim 12, wherein a top end of the remaining SiCO layer is fully enclosed by the bit line dielectric portion and the remaining silicon nitride layer that is not etched by the nitride etching process.

14. The method of claim 8, wherein the bit line dielectric portion is on a top of the bit line conductive portion.

15. The method of claim 8, wherein the bit line conductive portion comprises a tungsten portion, a polysilicon portion, and a diffusion barrier layer between the tungsten portion and the polysilicon portion.

16. A semiconductor memory device comprising:
a bit line structure on a substrate, wherein the bit line structure comprises a bit line conductive portion and a bit line dielectric portion;
a silicon carbon oxide (SiCO) layer on a sidewall of the bit line structure; and
a silicon nitride layer on the sidewall of the bit line structure, wherein a top end of the SiCO layer is fully enclosed by the bit line dielectric portion and the silicon nitride layer.

17. The semiconductor memory device of claim 16, wherein a top portion of the bit line dielectric portion is not covered by the SiCO layer.

18. The semiconductor memory device of claim 16, wherein the SiCO layer consists of 37% silicon, 48% oxygen and 15% carbon.

19. The semiconductor memory device of claim 16, wherein the bit line dielectric portion is on a top of the bit line conductive portion.

20. The semiconductor memory device of claim 16, wherein the bit line conductive portion comprises a tungsten portion, a polysilicon portion, and a diffusion barrier layer between the tungsten portion and the polysilicon portion.
